(19) United States
(12) Patent Application Publication
(10) Pub. No.: US 2026/0169637 A1
(43) Pub. Date: Jun. 18, 2026

(54) STORAGE DEVICE AND METHOD OF OPERATING THE STORAGE DEVICE

(71) Applicant: SK hynix Inc., Icheon-si Gyeonggi-do (KR)

(72) Inventor: Eun Young PARK, Icheon-si Gyeonggi-do (KR)

(73) Assignee: SK hynix Inc., Icheon-si Gyeonggi-do (KR)

(21) Appl. No.: 19/219,475

(22) Filed: May 27, 2025

(30) Foreign Application Priority Data
Dec. 17, 2024 (KR) 10-2024-0188911

(51) Int. Cl. G06F 3/06

(52) U.S. Cl. CPC G06F 3/0619; G06F 3/0653; G06F 3/0679

(57) ABSTRACT

A storage device include a nonvolatile memory device including a target memory region and a controller configured to control the nonvolatile memory device to perform a read operation on the target memory region, configured to determine whether at least one adjustment condition, among a plurality of adjustment conditions, is satisfied for access operations performed on the target memory region, and configured to determine a read count increment corresponding to the read operation based on the at least one adjustment condition. The plurality of adjustment conditions include a first adjustment condition in which variability between read temperatures is determined to be small based on a variability indicator of read temperatures at which a predetermined quantity of recent read operations are performed among the access operations.

### CROSS REFERENCE TO RELATED APPLICATION

The present application claims priority under 35 U.S.C. § 119(a) to Korean Patent Application No. 10-2024-0188911, filed in the Korean Intellectual Property Office on Dec. 17, 2024, the entire contents of which application is incorporated herein by reference.

### BACKGROUND

### 1. Technical Field

The present disclosure relates to a storage device including a memory device.

### 2. Related Art

A storage device stores data provided by an external device based on a write request from the external device. The storage device provides the external device with data stored in the storage device based on a read request from the external device. The external device is an electronic device capable of processing data and may be included in a computer, a digital camera, a mobile phone, and so forth. The storage device may be embedded in the external device or may be fabricated in a separate device that operates via electrical coupling to the external device. The storage device may include a memory device that stores data.

### SUMMARY

In an embodiment, a storage device may include a nonvolatile memory device including a target memory region and a controller configured to control the nonvolatile memory device to perform a read operation on the target memory region, configured to determine whether at least one adjustment condition, among a plurality of adjustment conditions, is satisfied for access operations performed on the target memory region, and configured to determine a read count increment corresponding to the read operation based on the at least one adjustment condition. The plurality of adjustment conditions may include a first adjustment condition in which variability between read temperatures is determined to be small based on a variability indicator of read temperatures at which a predetermined quantity of recent read operations are performed among the access operations.

In an embodiment, a method of operating a storage device may include controlling a nonvolatile memory device to perform a read operation on a target memory region, determining whether at least one adjustment condition, among a plurality of adjustment conditions, is satisfied for access operations performed on the target memory region, and determining a read count increment corresponding to the read operation based on the at least one adjustment condition. The plurality of adjustment conditions may include a first adjustment condition in which variability between read temperatures is determined to be small based on a variability indicator of read temperatures at which a predetermined quantity of recent read operations are performed.

In an embodiment, an method of operating a storage device may include performing, by a memory device, one or more access operations on a target memory region, determining characteristics of one or more performance index curves, wherein the one or more performance index curves may include one or more of a performance index curve for an erase temperature, a performance index curve for a program temperature, and a performance index curve for a read temperature, determining one or more performance index values corresponding to one or more access temperatures at which the one or more access operations are performed based on the one or more performance index curves, determining a read count increment based on one or more ratios of a reference performance index value to the one or more performance index values, and performing a management operation on the target memory region based on a read count increased by the read count increment.

In an embodiment, a method includes performing a plurality of access operations on a target memory region of a memory device; determining characteristics of a plurality of performance index curves; determining a performance index value corresponding to an access temperature at which the plurality of access operations is performed based on the plurality of performance index curves; determining a read count increment based on ratio of a reference performance index value to the performance index value; and performing a management operation on the target memory region based on a read count increased by the read count increment.

### BRIEF DESCRIPTION OF THE DRAWINGS

FIG. 1 is a block diagram illustrating a storage device according to an embodiment.

FIG. 2 is a table including adjustment values for a read count increment according to an embodiment.

FIG. 3 is a flowchart illustrating a method of operation of a controller according to an embodiment.

FIG. 4 and FIG. 5 are flowcharts illustrating a method of determining whether an adjustment condition for a read count increment is satisfied according to an embodiment.

FIG. 6 is a flowchart illustrating a method of determining a read count increment according to an embodiment.

FIG. 7A, FIG. 7B, and FIG. 7C include graphs of read permission count versus temperature according to an embodiment.

### DETAILED DESCRIPTION

Embodiments of the present technology are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Temperature may have a significant influence on operating performance and reliability of a storage device. A high-temperature environment may aggravate data retention characteristics by accelerating the leakage of charge within a memory cell of the memory device. A low-temperature environment may degrade program and read performance of the memory device by reducing current flow. The storage device may use various correction schemes corresponding to a temperature change to establish stable performance. The storage device may perform various management operations to prevent and solve data errors or damage that may occur when the storage device is subject to an abnormal or extreme temperature environment.

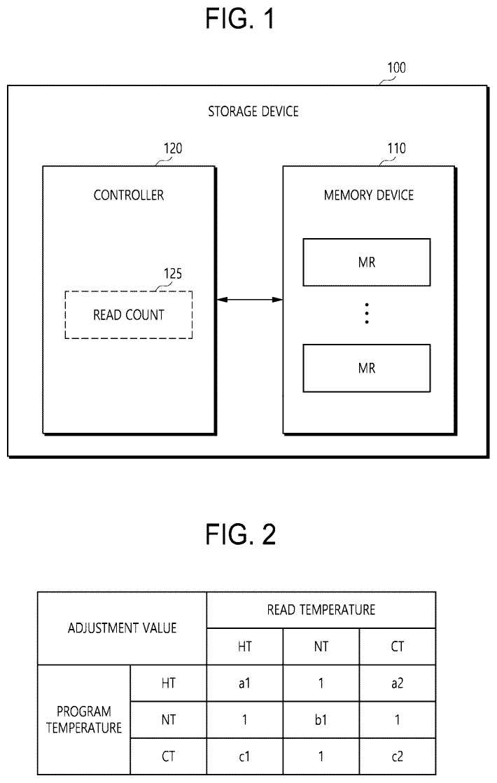

FIG. 1 is a block diagram illustrating a storage device 100 according to an embodiment.

The storage device 100 stores data received from an external host device (not illustrated) based on a write request from the host device. The storage device 100 transmits, to the host device, data stored in the storage device 100 based on a read request from the host device.

The storage device 100 includes a memory device 110 and a controller 120

The memory device 110 stores data under control of the controller 120, and outputs, to the controller 120, data stored in the memory device 110. The memory device 110 performs an access operation including accessing a memory region in which data are stored under the control of the controller 120. The access operation includes a program operation, a read operation, and an erase operation. The memory device 110 includes a plurality of memory regions MR in which data are stored.

The controller 120 controls the memory device 110. The controller 120 stores, in the memory device 110, data transmitted by the host device based on a write request from the host device. The controller 120 reads data from the memory device 110 based on a read request from the host device and transmits the read data to the host device.

The controller 120 performs a management operation on the memory device 110 to extend the lifespan of the memory device 110 and improve data reliability. The management operation includes a wear-leveling operation, a garbage collection operation, a reprogram operation, and a parameter adjustment operation. The parameter adjustment operation includes adjusting various operating voltages, such as a read voltage, a program voltage, a verify voltage, a pass voltage, a precharge voltage, and an erase voltage, a reference voltage, a reference value, an initial value, timing, and an offset value, which are used during operation of the memory device 110. The controller 120 performs the management operation independently of the host device, for example, when the controller does not receive a request from the host device. According to an embodiment, the controller 120 performs the management operation based on a request from the host device.

The controller 120 performs the management operation based on a read count 125. For example, the controller 120 performs the management operation whenever the read count 125 is larger than a predetermined reference value. The term “predetermined” includes a value established before the parameter is used during a process or algorithm when the parameter is used in relation to timing, time, a conversion algorithm, a preamble, an edge, an interval code, a level, or a voltage level, for example. According to an embodiment, the value of a parameter is determined before a process or algorithm is started. According to an embodiment, the value of a parameter is determined while a process or algorithm is in progress, but is determined before the parameter is used during the process or algorithm. The controller 120 increases the read count 125 by a read count increment for each read operation performed by the memory device 110.

A high-temperature environment may aggravate or deteriorate a data retention characteristic by accelerating the leakage of charge within a memory cell. A low-temperature environment may degrade program and read performance of a memory device by reducing the flow of a current. The controller 120 uses a read count increment that compensates for temperature.

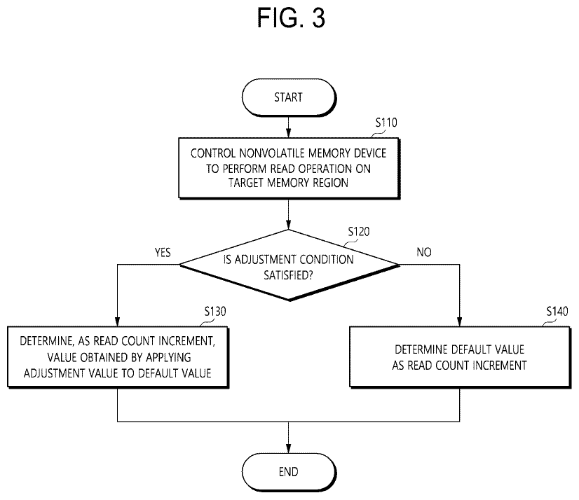

FIG. 2 is a table including adjustment values for a read count increment according to an embodiment. In FIG. 2, each adjustment value a1, a2, b1, c1, and c2 is a value greater than 1, for example.

Referring to FIG. 2, a temperature range is divided into a hot temperature range HT, a normal temperature range NT, and a cold temperature range CT. Depending on an embodiment, the quantity of temperature ranges may vary.

To apply a temperature correction to the read count increment, an adjustment value of the read count increment is determined based on at least one of a program temperature and a read temperature. According to an embodiment, the adjustment value may be a weight that is multiplied by a default or base value of the read count increment, such as 1.

For example, when a program temperature is included in the hot temperature range HT and a read temperature is included in the cold temperature range CT with respect to a target memory region on which a read operation is performed, an adjustment value may be determined as a2. In this example, a read count increment is determined as a value for which a default value is multiplied by a2.

For example, when a program temperature is in the hot temperature range HT and a read temperature is in the normal temperature range NT with respect to a target memory region on which a read operation is performed, an adjustment value is determined as 1. In this example, a read count increment is determined as the default or base value. For example, when a program temperature is in the hot temperature range HT and a read temperature is in the normal temperature range NT with respect to a target memory region on which a read operation is performed, a read count increment is not adjusted, and the read count increment is determined as a default or base value.

When variability between an erase temperature, a program temperature, and a read temperature is large, the data stability of a target memory region is degraded. The data stability of a target memory region is degraded when variability is small between read temperatures that are repeated for the target memory region. According to previous methods, variability between access temperatures might not be properly incorporated into temperature compensation because previous methods only determined which temperature range each access temperature for a target memory region falls within in order to determine a read count increment.

When the read count increment is large, the management operation is performed at a time before data are corrupted because the read count 125 quickly reaches a predetermined reference value for the management operation. When the management operation is performed too frequently, a problem may result, such as performance degradation of the storage device 100 or increase in power consumption. Accordingly, appropriate temperature compensation is applied to obtain a read count increment.

Referring to FIG. 1, to determine a read count increment with respect to each read operation performed on a target memory region by the memory device 110, the controller 120 determines whether a predetermined adjustment condition is satisfied. When the predetermined adjustment condition is not satisfied, the controller 120 determines a default value as the read count increment, such as 1. When the predetermined adjustment condition is satisfied, the controller 120 determines, as the read count increment, a value obtained by applying an adjustment value to a default value. The adjustment value may be a weight that is multiplied by the default value, for example. For example, the adjustment value may be a value applied to the default value according to one of various arithmetic operations.

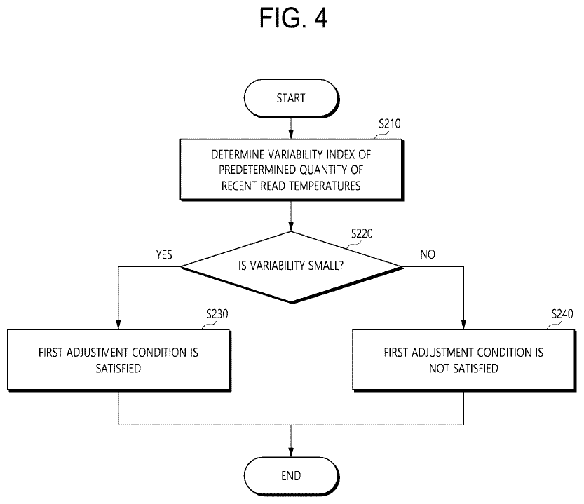

To determine a predetermined adjustment condition, the controller 120 refers to access temperatures at which access operations are performed on a target memory region. The access temperatures include an erase temperature at which the most recent erase operation is performed on a target memory region, referred to as the “most recent erase temperature.” The access temperatures include a program temperature at which the most recent program operation is performed on a target memory region, referred to as the “most recent program temperature.” The access temperatures includes read temperatures at which a predetermined quantity of recent read operations are performed on a target memory region, referred to as “recent read temperatures.” A read temperature at which the most recent read operation is performed on a target memory region is referred as the “most recent read temperature.” The most recent read operation that is performed on a target memory region is a read operation that triggers or causes a read count to increase. A method of determining, by the controller 120, a read count increment with reference to the access temperatures is described with reference to FIG. 3 to FIG. 7.

According to an embodiment, the controller 120 counts or tracks the read count 125 in units of memory regions included in the memory device 110, for example, a page, a word line, a memory block, a group of memory blocks, a plane, a memory die, a memory chip, and so forth.

The storage device 100 may include a personal computer memory card international association (PCMCIA) card, a smart media card, a memory stick, various multimedia cards (such as an MMC, an eMMC, an RS-MMC, and MMC-micro), secure digital (SD) cards (such as SD, Mini-SD, and Micro-SD), universal flash storage (USF), or a solid state drive (SSD).

The memory device 110 may include NAND flash memory, NOR flash memory, resistive random access memory (RRAM), phase-change memory (PRAM), magnetoresistive random access memory (MRAM), ferroelectric random access memory (FRAM), or spin transfer torque random access memory (STT-RAM).

FIG. 3 is a flowchart illustrating a method of operation of the controller 120 according to an embodiment. The processes of the flowchart may be performed in a different order and may include fewer or additional processes than described and shown in FIG. 3.

Referring to FIG. 3, the controller 120 controls S110 a nonvolatile memory device to perform a read operation on a target memory region.

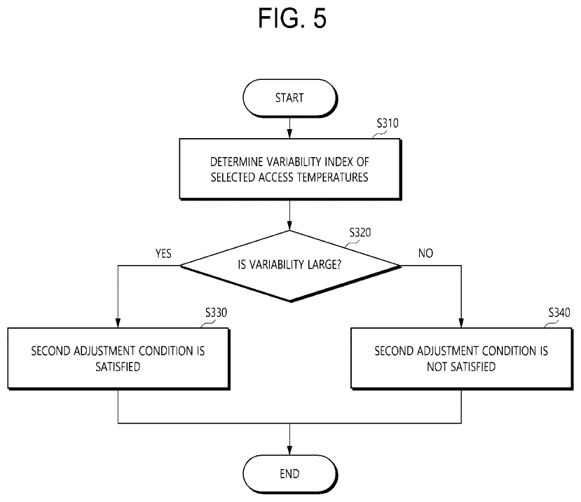

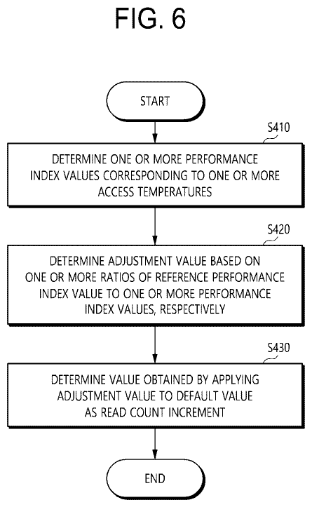

The controller 120 determines S120 whether at least one adjustment condition, among a plurality of adjustment conditions, is satisfied with respect to access operations performed on the target memory region. A method of determining whether the adjustment condition is satisfied is described with reference to FIG. 4 and FIG. 5.

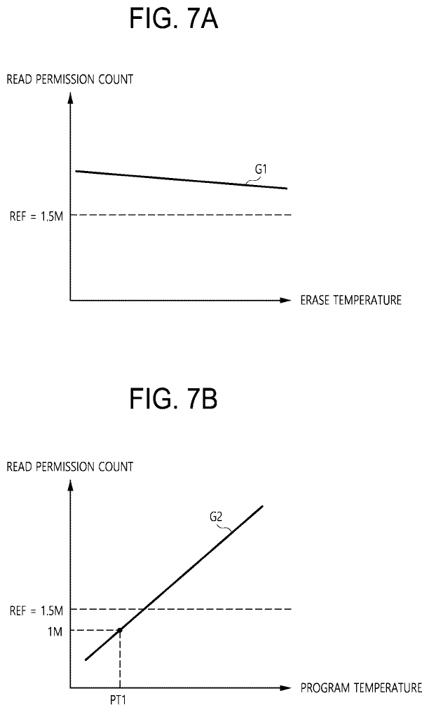

When the at least one adjustment condition is determined S120 to be satisfied, the method continues with the controller 120 determining S120, as a read count increment, a value obtained by applying an adjustment value to the default value. The adjustment value may be any real number, including negative values. A method of determining the read count increment is described with reference to FIG. 6.

When the at least one adjustment condition is determined S120 not to be satisfied, the controller 120 determines S140 or establishes a default value as a read count increment.

FIG. 4 and FIG. 5 are flowcharts illustrating methods of determining, by the controller 120, whether an adjustment condition for a read count increment is satisfied according to an embodiment. The processes of the flowchart may be performed in a different order and may include fewer or additional processes than described and shown in FIG. 4. The processes of the flowchart may be performed in a different order and may include fewer or additional processes than described and shown in FIG. 5.

Referring to FIG. 4, the controller 120 determines S210 the variability index, also referred to as a variability indicator, of read temperatures, referred to as “recent read temperatures,” at which a predetermined quantity of recent read operations are performed among access operations performed on a target memory region. The predetermined quantity may be 2 or more. The predetermined quantity of read operations repeatedly applies stress to the target memory region. The variability index includes at least one among a standard deviation, an average absolute deviation, variance, the ratio of a minimum value and a maximum value, and a difference between a minimum value, a maximum value, and so forth.

The controller 120 determines S220 whether variability between the recent read temperatures is small based on the variability index of the recent read temperatures. For example, when a variability index that is in direct proportion to the variability is less than a predetermined reference value, the controller 120 determines that the variability is small. For example, when a variability index that is in reverse proportion to variability is larger than a predetermined reference value, the controller 120 determines that variability is small.

When variability between recent read temperatures is determined S220 as small,, the controller 120 determines S230 that a first adjustment condition is satisfied.

When variability between recent read temperatures is determined S220 to be large, the controller 120 determines S240 that a first adjustment condition is not satisfied.

Referring to FIG. 5, in operation S310, the controller 120 determines S310 the variability index, also referred to as a variability indicator, of access temperatures, referred to as “selected access temperatures,” at which selected access operations are performed among access operations performed on a target memory region. The selected access temperatures include the most recent erase temperature, the most recent program temperature, and a read temperature at which the first read operation is performed on a target memory region after the most recent program operation among previously performed program operations. The variability index, or variability indicator, includes at least one among a standard deviation, an average absolute deviation, variance, the ratio of a minimum value and a maximum value, a difference between a minimum value and a maximum value, and so forth.

The controller 120 determines S320 whether variability between the selected access temperatures is large based on the variability index of the selected access temperatures. For example, when a variability index that is in direct proportion to variability is larger than a predetermined reference value, the controller 120 determines that the variability is large. For example, when a variability index that is in reverse proportion to the variability is less than a predetermined reference value, the controller 120 determines that the variability is large.

When the variability between the selected access temperatures is determined S320 to be large, the controller 120 determines S330 that a second adjustment condition is satisfied.

When the variability between the selected access temperatures is determined S320 to be small, or not large, the controller 120 determines S340 that a second adjustment condition is not satisfied.

According to an embodiment, the controller 120 determines S120 only whether the first adjustment condition, among adjustment conditions, is satisfied in FIG. 3. According to an embodiment, the controller 120 determines S120 only whether the second adjustment condition, among the adjustment conditions, is satisfied. According to an embodiment, the controller 120 determines S120 whether both the first adjustment condition and the second adjustment condition are satisfied. Three or more adjustment conditions may be utilized.

According to an embodiment, temperature compensation may be applied to a read count increment by considering variability between access temperatures for a target memory region.

FIG. 6 is a flowchart illustrating a method of determining, by the controller 120, a read count increment according to an embodiment.

Referring to FIG. 6, the controller 120 determines S410 one or more performance index values corresponding to one or more access temperatures at which one or more selected access operations are performed among access operations performed on a target memory region.

According to an embodiment, one or more access temperatures at which one or more access operations are performed include one or more of the most recent erase temperature, the most recent program temperature, and the most recent read temperature. To determine the one or more performance index values, the controller 120 refers to one or more relationships between temperature and performance index value that may be represented as performance index curves, among a performance index curve for an erase temperature, a performance index curve for a program temperature, and a performance index curve for a read temperature. For example, the performance index curve for the erase temperature indicates performance index values corresponding to erase temperatures.

According to an embodiment, the performance index is an index indicative of performance of the memory device 110 and may include a read permission count, an error rate, the quantity of error bits, a timing margin, a voltage margin, and so forth.

The controller 120 determines S420 an adjustment value for a read count increment based on one or more ratios of a predetermined reference performance index value to the one or more performance index values.

According to an embodiment, the controller 120 determines an adjustment value function, among predetermined adjustment value functions, based on which adjustment condition, among the adjustment conditions, is satisfied and determines the adjustment value of the read count increment by including one or more ratios in the determined adjustment value function.

According to an embodiment, the controller 120 determines the adjustment value of the read count increment based on one or more selected ratios excluding one or more unselected ratios, among the one or more ratios. For example, the one or more unselected ratios includes the ratio of the reference performance index value to a performance index value determined based on a performance index curve in which the absolute value of a slope is less than a predetermined reference value, among one or more performance index curves. When the absolute value of the slope is less than a predetermined reference value indicates that a corresponding performance index curve has little dependence on access temperature, thus a corresponding ratio is negligible.

The controller 120 determines S430 a value obtained by applying the adjustment value to a default value as a read count increment.

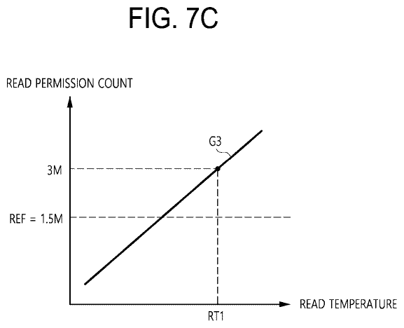

FIG. 7A to FIG. 7C include graphs of read permission count versus temperature according to an embodiment.

Referring to FIG. 7A to FIG. 7C, a read permission count is used as a performance index. A curve G1 in FIG. 7A indicates a relationship between read permission count and an erase temperature, a curve G2 in FIG. 7B indicates a relationship between read permission count and a program temperature, and a curve G3 in FIG. 7C indicates a relationship between read permission count for a read temperature are included in the performance index curves shown in the performance index graphs. The read permission count refers to the quantity of read operations by which data stored in a memory cell can withstand a read disturbance influence, for example. The curve G1 indicates a read permission count versus erase temperature. The curve G2 indicates a read permission count versus program temperature. The curve G3 indicates a read permission count versus read temperature.

At least one characteristic represents each of the curves G1, G2, and G3 and is stored in a separate storage region of the memory device 110. The characteristic of each curve includes, for example, various mathematical attributes or relationships that describe a form and change of the curve, such as a slope, an intercept, curvature, an increase/decrease, symmetry, an inflection point, extreme values, endpoints, and so forth. Characteristics of each curve may be determined during a process of manufacturing the memory device 110 or by performing, by the controller 120, a test operation on the memory device 110. According to an embodiment, the controller 120 periodically updates the characteristic of each curve G1, G2, and G3. The controller 120 reads the one or more characteristics of each curve stored in the memory device 110 and use the one or more characteristics of each curve to determine the adjustment value of the read count increment.

Each of the curves G1, G2, and G3 is illustrated in the form of a log scale and are linear. Relationships between read permission count and temperature other than the relationships shown in curves G1, G2, and G3 may be utilized. The slope of the curve G1 is determined from read permission counts corresponding to at least two erase temperatures. The controller 120 may determine a read permission count corresponding to the most recent erase temperature of a target memory region from at least any one point in the curve G1 and the slope of the curve G1. The controller 120 may determine a read permission count corresponding to the most recent program temperature of a target memory region based on the curve G2. The controller 120 may determine a read permission count corresponding to the most recent read temperature of a target memory region based on the curve G3.

When a read permission count is used as a performance index, a reference read permission count REF is used as a reference performance index value. The ratio of the reference read permission count REF to the read permission count corresponding to the most recent erase temperature, referred to as a “first ratio,” is determined based on Equation 1.

Equation 1: first ratio=reference read permission count REF/read permission count corresponding to most recent erase temperature.

The ratio of the reference read permission count REF to a read permission count corresponding to the most recent program temperature, referred to as a “second ratio,” is determined based on Equation 2.

Equation 2: second ratio =reference read permission count REF/read permission count corresponding to most recent program temperature.

The ratio of the reference read permission count REF to a read permission count corresponding to the most recent read temperature, referred to as a “third ratio,” is determined based on Equation 3.

Equation 3: third ratio=reference read permission count REF/read permission count corresponding to most recent read temperature.

The adjustment value of the read count increment is determined based on an adjustment value function f1 in Equation 4.

Equation 4: adjustment value of read count increment=f1(the first ratio, the second ratio, the third ratio).

According to an embodiment, the adjustment value of the read count increment is determined based on one or more selected ratios among the first ratio, the second ratio, and the third ratio and not based on one or more unselected ratios among the first ratio, the second ratio, and the third ratio. Thus, the adjustment value function f1, utilizes one or more selected ratios during the read count increment determination and does not utilize one or more unselected ratios during the read count increment determination. The one or more unselected ratios may be the ratio of the reference read permission count REF to a read permission count that is determined based on a curve, among the curves G1, G2, and G3, in which the absolute value of a slope is less than a predetermined reference value. For example, when an absolute value of a slope in the curve G1 is less than a predetermined reference value, the first ratio of the adjustment value function f1 is not utilized, and an adjustment value of a read count increment is determined based on the second ratio and the third ratio and not based on the first ratio.

According to an embodiment, the first ratio of the adjustment value function f1 is not utilized, and the adjustment value function f1 is a multiplication of the second ratio and the third ratio. For example, when a read permission count corresponding to the most recent program temperature PT1 is 1 million in the curve G2, a read permission count corresponding to the most recent read temperature RT1 is 3 million in the curve G3, and the reference read permission count REF is 1.5 million, an adjustment value of a read count increment is 0.75, for example, 1.5 M/1 M*1.5 M/3 M. When the adjustment value of the read count increment is a weight multiplied by a default value, such as 1, of the read count increment, the read count increment is 0.75, for example, 1*0.75.

According to an embodiment, the first ratio of the adjustment value function f1 is not utilized, and the adjustment value function f1 is determined as subtraction of the third ratio from the second ratio. For example, when a read permission count corresponding to the most recent program temperature PT1 is 1 million, a read permission count corresponding to the most recent read temperature RT1 is 3 million, and the reference read permission count REF is 1.5 million, an adjustment value of a read count increment is 1, for example, 1.5 M/1 M-1.5 M/3 M. When the adjustment value of the read count increment is a weight multiplied by a default value, such as 1, of the read count increment, the read count increment is 1, for example, 1*1.

According to an embodiment, the controller 120 determines an adjustment value of a read count increment based on an adjustment value function other than the adjustment value function f1 depending on which adjustment condition is satisfied. For example, the controller 120 uses the adjustment value function f1 when only the first adjustment condition is satisfied, uses the adjustment value function f2 when only the second adjustment condition is satisfied, and uses the adjustment value function f3 when the first adjustment condition and the second adjustment condition are satisfied.

According to an embodiment, when a performance index other than a read permission count is used to determine an adjustment value of a read count increment, the controller 120 determines the adjustment value of the read count increment using a curve of the other performance index and a method similar to the method using the read permission count.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A storage device comprising:
a nonvolatile memory device comprising a target memory region; and
a controller configured to control the nonvolatile memory device to perform a read operation on the target memory region, configured to determine whether at least one adjustment condition, among a plurality of adjustment conditions, is satisfied for access operations performed on the target memory region, and configured to determine a read count increment corresponding to the read operation based on the at least one adjustment condition;
wherein the plurality of adjustment conditions comprises a first adjustment condition in which variability between read temperatures is determined to be small based on a variability indicator of read temperatures at which a predetermined quantity of recent read operations are performed among the access operations.

2. The storage device of claim 1,
wherein the plurality of adjustment conditions further comprise a second adjustment condition in which variability between access temperatures is determined to be large based on a variability indicator of a plurality of access temperatures at which at least one selected access operation is performed among the access operations; and
wherein the plurality of access temperatures comprise an erase temperature at which a most recent erase operation is performed, a program temperature at which a most recent program operation is performed, and a read temperature at which a first read operation after the program operation is performed among the access operations.

3. The storage device of claim 1, wherein the variability indicator comprises at least one of a standard deviation, an average absolute deviation, variance, a ratio of a minimum value and a maximum value, and a difference between a minimum value and a maximum value.

4. The storage device of claim 1, wherein the controller is configured to:
determine an adjustment value function, among a plurality of predetermined adjustment value functions, based on which adjustment condition is satisfied among the plurality of adjustment conditions; and
determine an adjustment value of the read count increment based on the adjustment value function.

5. The storage device of claim 1, wherein the controller is configured to:
determine one or more performance index values corresponding to one or more access temperatures at which at least one selected access operation is performed, among the access operations, based on at least one adjustment condition satisfied among the plurality of adjustment conditions;
determine an adjustment value based on one or more ratios of a reference performance index value to the one or more performance index values; and
determine, as the read count increment, a value obtained by applying the adjustment value to a default value.

6. The storage device of claim 5, wherein the one or more access temperatures comprise one or more of an erase temperature at which a most recent erase operation is performed, a program temperature at which a most recent program operation is performed, and a read temperature at which the read operation is performed.

7. The storage device of claim 5, wherein the controller is configured to determine one or more performance index values by utilizing characteristics of one or more performance index curves among a performance index curve for an erase temperature, a performance index curve for a program temperature, and a performance index curve for a read temperature.

8. The storage device of claim 7,
wherein the controller is configured to determine the adjustment value based on one or more selected ratios among the one or more ratios; and
wherein one or more unselected ratios comprise a ratio of the reference performance index value to a performance index value determined based on a performance index curve for which an absolute value of a slope is less than a reference value among the one or more performance index curves.

9. The storage device of claim 1, wherein the controller is configured to determine a default value as the read count increment based on a determination that at least one adjustment condition is not satisfied among the plurality of adjustment conditions.

10. The storage device of claim 1, wherein the controller is configured to:
increase a read count by the read count increment; and
perform a management operation on the target memory region based on the read count.

11. A method of operating a storage device, the method comprising:
controlling a nonvolatile memory device to perform a read operation on a target memory region;
determining whether at least one adjustment condition, among a plurality of adjustment conditions, is satisfied for access operations performed on the target memory region; and
determining a read count increment corresponding to the read operation based on the at least one adjustment condition;
wherein the plurality of adjustment conditions comprise a first adjustment condition in which variability between read temperatures is determined to be small based on a variability indicator of read temperatures at which a predetermined quantity of recent read operations are performed.

12. The method of claim 11,
wherein the plurality of adjustment conditions comprise a second adjustment condition in which variability between the plurality of access temperatures is determined to be large based on a variability indicator of access temperatures at which at least one selected access operation is performed among the access operations; and
wherein the plurality of access temperatures comprise an erase temperature at which a most recent erase operation is performed, a program temperature at which a most recent program operation is performed, and a read temperature at which a first read operation after the program operation is performed.

13. The method of claim 11, wherein the variability indicator comprises at least one of a standard deviation, an average absolute deviation, variance, a ratio of a minimum value and a maximum value, and a difference between a minimum value and a maximum value.

14. The method of claim 11, wherein determining of read count increment comprises:
determining an adjustment value function, among plurality of predetermined adjustment value functions, based on which adjustment condition is satisfied among the plurality of adjustment conditions; and
determining an adjustment value of the read count increment based on the adjustment value function.

15. The method of claim 11, wherein determining the read count increment comprises:
determining one or more performance index values corresponding to one or more access temperatures at which at least one selected access operation is performed, among the access operations, based on at least one adjustment condition satisfied among the plurality of adjustment conditions;,
determining an adjustment value based on one or more ratios of a reference performance index value to the one or more performance index values; and
determining, as the read count increment, a value obtained by applying the adjustment value to a default value.

16. The operating method of claim 15, wherein the one or more access temperatures comprise one or more of an erase temperature at which a most recent erase operation is performed, a program temperature at which a most recent program operation is performed, and a read temperature at which the read operation is performed.

17. The method of claim 15, wherein determining the one or more performance index values comprises utilizing characteristics of one or more performance index curves, among a performance index curve for an erase temperature, a performance index curve for a program temperature, and a performance index curve for a read temperature.

18. The method of claim 17,
wherein determining the adjustment value comprises determining the adjustment value based on one or more selected ratios among the one or more ratios; and
wherein one or more unselected ratios comprise a ratio of the reference performance index value to a performance index value determined based on a performance index curve for which an absolute value of a slope is less than a reference value, among the one or more performance index curves.

19. The method of claim 11, wherein determining the read count increment comprises determining a default value as the read count increment based on a determination that at least one adjustment condition is not satisfied among the plurality of adjustment conditions.

20. The method of claim 11, further comprising:
increasing a read count by the read count increment; and
performing a management operation on the target memory region based on the read count.

21. A method of operating a storage device, the method comprising:
performing, by a memory device, one or more access operations on a target memory region;
determining characteristics of one or more performance index curves, wherein the one or more performance index curves comprise one or more of a performance index curve for an erase temperature, a performance index curve for a program temperature, and a performance index curve for a read temperature;
determining one or more performance index values corresponding to one or more access temperatures at which the one or more access operations are performed based on the one or more performance index curves;
determining a read count increment based on one or more ratios of a reference performance index value to the one or more performance index values; and
performing a management operation on the target memory region based on a read count increased by the read count increment.

22. The method of claim 21, wherein the one or more access temperatures comprises one or more of an erase temperature at which a most recent erase operation is performed, a program temperature at which a most recent program operation is performed, and a read temperature at which a most recent read operation is performed.

23. The method of claim 21,
wherein determining the read count increment comprises determining an adjustment value of the read count increment based on one or more selected ratios among the one or more ratios; and
wherein the one or more unselected ratios comprise a ratio of the reference performance index value to a performance index value determined based on a performance index curve for which an absolute value of a slope is less than a reference value, among the one or more performance index curves.

24. The method of claim 21, further comprising performing test operations on the memory device at different access temperatures to determine the characteristics of the one or more performance index curves.

25. The method of claim 21, further comprising reading the characteristics of the one or more performance index curves from the memory device.

26. The method of claim 21, wherein a performance index of the performance index curves comprises one of a read permission count, an error rate, a quantity of error bits, a timing margin, and a voltage margin.
